(19) United States
(12) Patent Application Publication
(10) Pub. No.: US 2025/0203254 A1
(43) Pub. Date: Jun. 19, 2025

(54) SPEAKER MODULE

(71) Applicants: AAC ACOUSTIC TECHNOLOGIES (SHENZHEN) CO., LTD., Shenzhen (CN); AAC Microtech (Changzhou) Co., Ltd., Changzhou City, Jiangsu Province (CN)

(72) Inventors: Shuwen Wu, Shenzhen (CN); Zhenfan Ge, Shenzhen (CN)

(21) Appl. No.: 17/921,978

(22) PCT Filed: Apr. 20, 2022
(86) PCT No.: PCT/CN2022/087942

§ 371 Date: Mar. 12, 2025

(30) Foreign Application Priority Data
Apr. 7, 2022 (CN) 202210361109.2

(51) Int. Cl. H04R 1/02

(52) U.S. Cl. CPC H04R 1/02

(57) ABSTRACT

The present application provides a speaker module, included a casing, a speaker driver arranged in an accommodating cavity of the casing, and a heat dissipation bracket. The heat dissipation bracket includes a body portion. A part of the body portion is arranged in the accommodation cavity, and the other part of the body portion is arranged outside the casing. One end of the body portion located outside the casing is provided with an extension portion bent and extended upward along a thickness direction of the speaker module, and the extension portion is in abutted against the heat dissipation members outside the speaker module. The body portion is provided with a first cooling channel, which is arranged around the speaker driver. The extension portion is provided with a second cooling channel communicated with the first cooling channel. The heat dissipation bracket provided by the present application has high heat dissipation efficiency.

### TECHNICAL FIELD

The present application relates to the technical field of speakers, in particular to a speaker module.

### BACKGROUND

A speaker module in the prior art includes a speaker driver arranged in an accommodating cavity and a heat dissipation bracket arranged around the speaker driver. When the speaker driver vibrates during operation, the heat generated by the speaker driver is transferred to the accommodating cavity through the heat dissipation bracket.

### SUMMARY OF THE INVENTION

### Technical Problem

However, it leads to poor heat dissipation efficiency of the speaker module by this heat dissipation method, and there is a risk of damage to the speaker driver due to a high temperature in the accommodating cavity.

Therefore, it is necessary to provide a speaker module with high heat dissipation efficiency.

### Solution to the Problem

### Technical Solution

An object of the present application is to provide a speaker module with high heat dissipation efficiency.

The technical solutions of the present application are as follows: a speaker module, comprising:
a casing provided with an accommodating cavity;
a speaker driver arranged in the accommodating cavity;
a heat dissipation bracket, comprising a body portion, wherein a part of the body portion is arranged in the accommodation cavity, and the other part of the body portion is arranged on an outer side of the casing; one end of the body portion located on the outer side of the casing is provided with an extension portion that is bent and extended upward along a thickness direction of the speaker module, and the extension portion is abutted against heat dissipation members outside the speaker module;
the body portion is provided with a first cooling channel, wherein the first cooling channel is arranged around the speaker driver; the extension portion is provided with a second cooling channel communicated with the first cooling channel; the second cooling channel is extended away from the speaker driver along the thickness direction of the speaker module, and the first cooling channel and the second cooling channel are filled with cooling liquid.

In one possible design, a plane where an axis of the first cooling channel is located is a first plane, a plane where an axis of the second cooling channel is located is a second plane, and there is a preset angle between the first plane and the second plane.

In one possible design, the first cooling channel comprises a first channel and a second channel that are oppositely arranged along the first direction, and a third channel extended along the first direction and capable of communicating with the first channel and the second channel;
the second cooling channel comprises a fourth channel extended along the first direction, a fifth channel extended along the third direction and capable of communicating with the fourth channel and the second channel, and a sixth channel capable of communicating with the first channel and the fourth channel;
the first direction is perpendicular to the third direction.

In one possible design, an inner diameter of the sixth channel is smaller than an inner diameter of the fifth channel.

In one possible design, one end of the first channel is provided with a first bent channel extended toward the second channel along the first direction, and a second bent channel extended along the second direction and capable of communicating with the first bent channel and the sixth channel;
one end of the second channel is provided with a third bent channel extended toward the first channel along the first direction, and a fourth bent channel extended along the second direction and capable of communicating with the third bent channel and the fifth channel;
the second direction is perpendicular to both the first direction and the third direction.

In one possible design, the heat dissipation bracket is provided with a first through hole arranged through a side wall of the heat dissipation bracket along the second direction, and at least part of the first through hole is located in a space enclosed by the second cooling channel.

In one possible design, the heat dissipation bracket comprises an upper bracket and a lower bracket, wherein the upper bracket comprises a first body and a first extension portion, and the lower bracket comprises a second body and a second extension portion;
the first body and the second body are stacked along the third direction, and the first extension portion and the second extension portion are stacked along the second direction.

In one possible design, the first body is provided with a first groove channel; the first extension portion is provided with a second groove channel; the second body is provided with a third groove channel, and the second extension portion is provided with a fourth groove channel;
after the upper bracket and the lower bracket are connected, the first groove channel and the third groove channel enclose the first cooling channel, and the second groove channel and the fourth groove channel enclose the second cooling channel.

In one possible design, the upper bracket is provided with a mounting hole; the lower bracket is provided with a mounting groove; the mounting hole is arranged opposite to the mounting groove, and a part of the speaker driver is extended into the mounting hole and is abutted against a bottom wall of the mounting groove;
the bottom wall of the mounting groove is provided with a second through hole, and a part of the speaker driver is exposed in the accommodating cavity through the second through hole.

In one possible design, a material of the heat dissipation bracket is metal.

It should be understood that the above general description and the detailed description that follows are merely exemplary and do not limit the present application.

### BENEFICIAL EFFECT OF THE INVENTION

### Beneficial Effect

The present application has the following beneficial effects. An interior of the heat dissipation bracket is provided with a first cooling channel surrounding the speaker driver and configured to accommodated the cooling liquid, and a second cooling channel abutted against a middle frame and configured to accommodated the cooling liquid. Therefore, the heat generated by the vibration of the speaker driver can be transferred to the heat dissipation bracket, and then transferred to the outside through the cooling liquid in the first cooling channel and the second cooling channel, and the high-temperature cooling liquid in the first cooling channel flows from the second cooling channel under the action of the pressure difference, so as to realize the circulating flow of the cooling liquid, thereby improving the heat dissipation efficiency of the heat dissipation bracket.

### BRIEF DESCRIPTION OF THE DRAWINGS

### Description of the Drawings

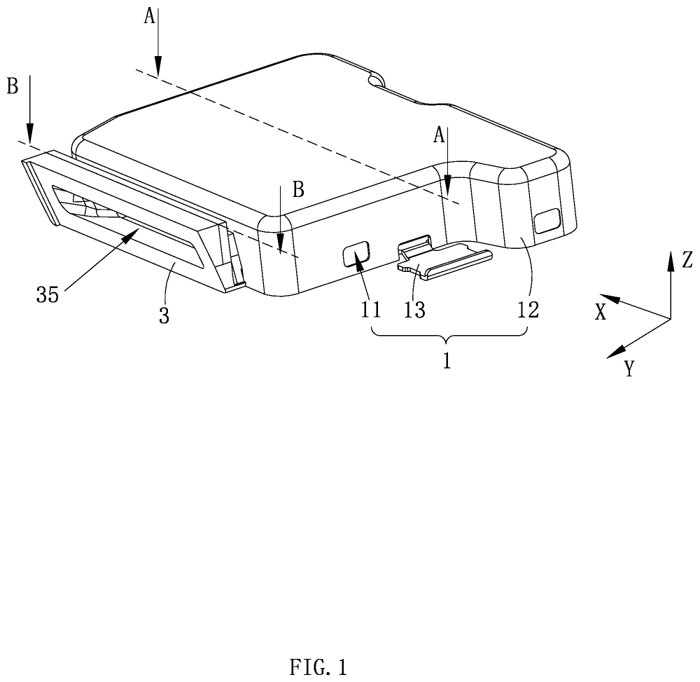

FIG. 1 is a partial structural view of a speaker module according to an embodiment of present application.

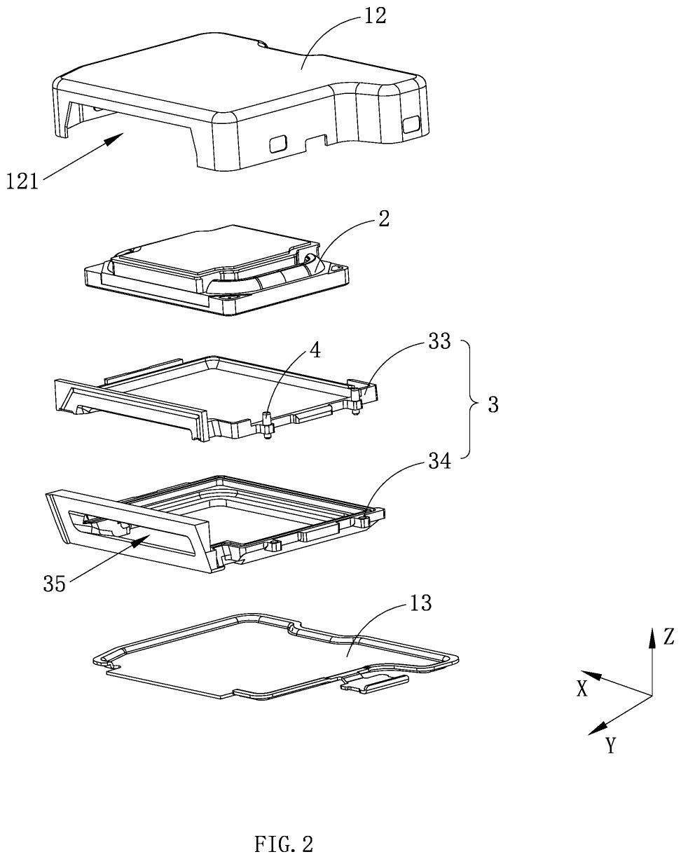

FIG. 2 is an exploded view of the speaker module in FIG. 1.

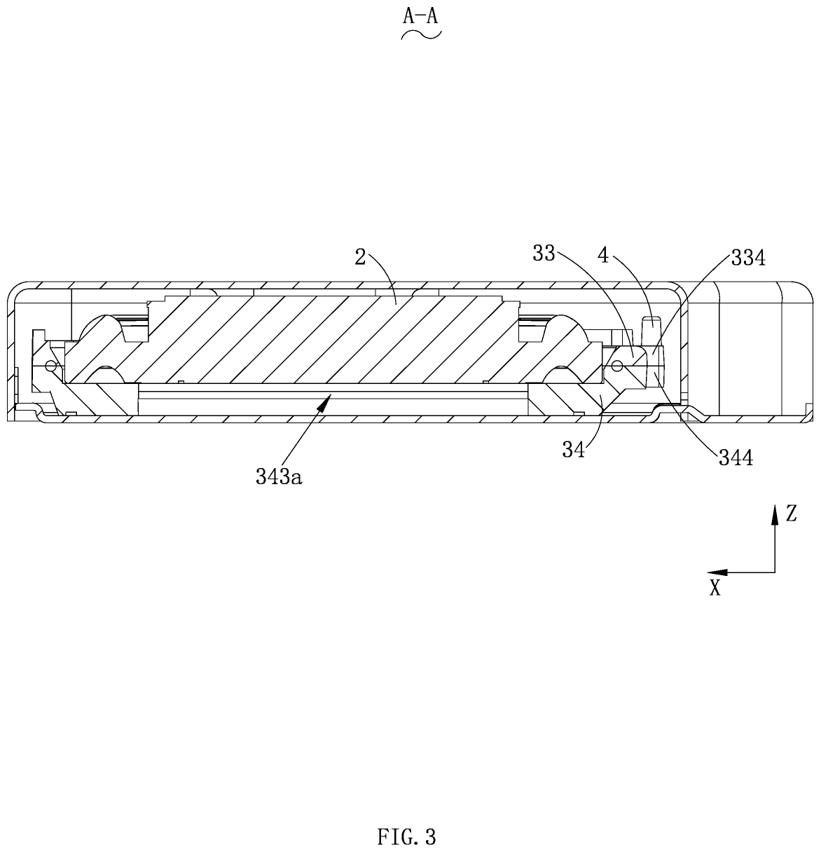

FIG. 3 is a sectional view taken along a line A-A in FIG. 1.

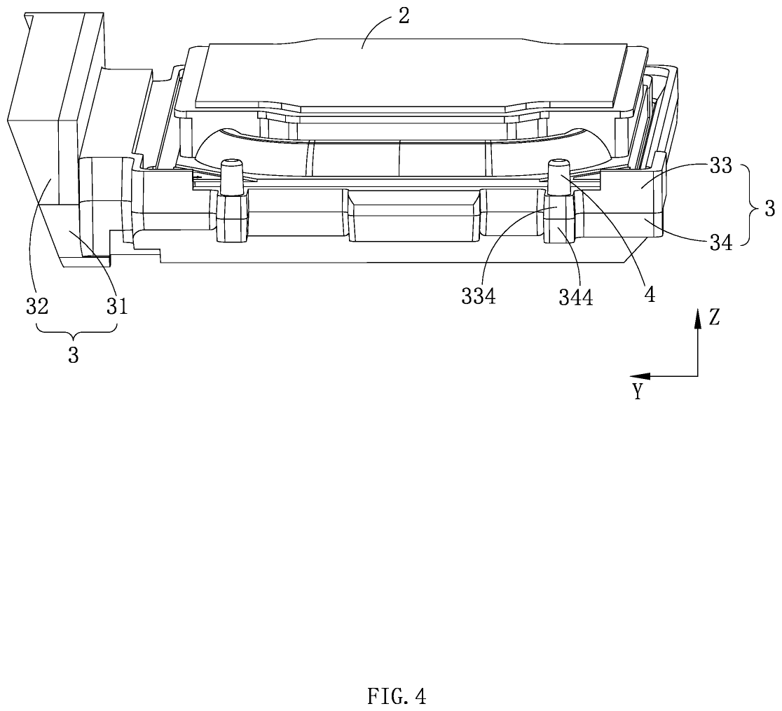

FIG. 4 is a schematic view of the speaker module with a casing removed in FIG. 1.

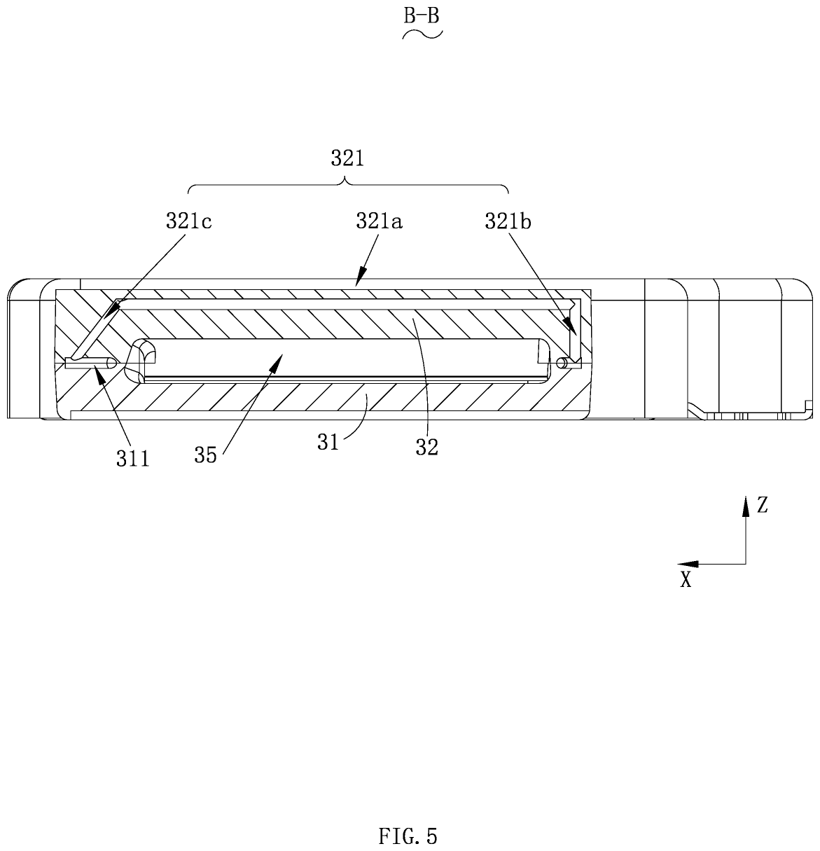

FIG. 5 is a sectional view taken along a line B-B in FIG. 1.

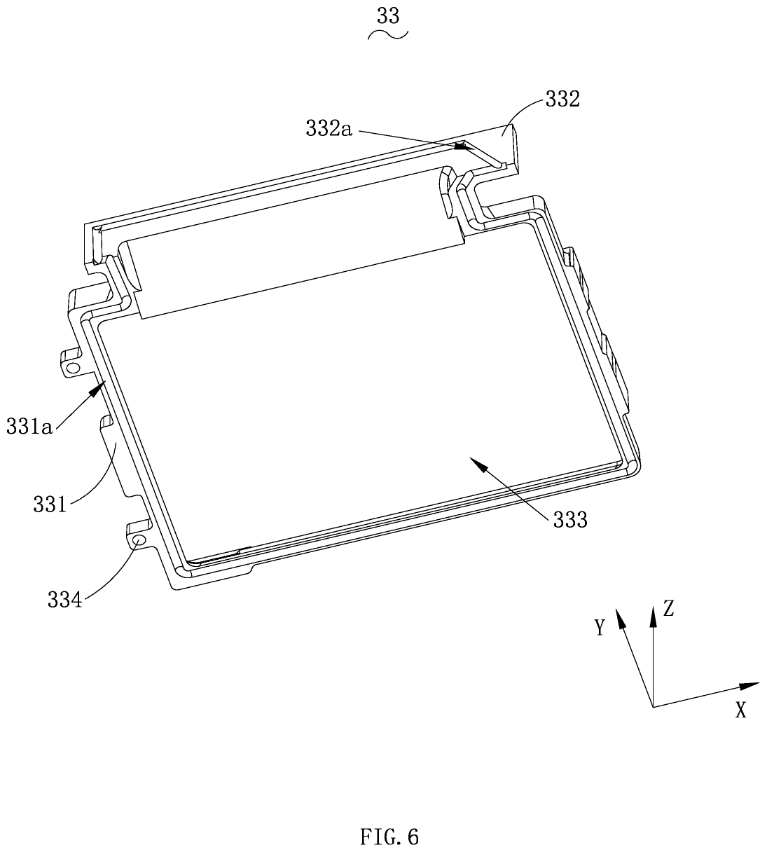

FIG. 6 is a bottom view of an upper bracket in FIG. 2.

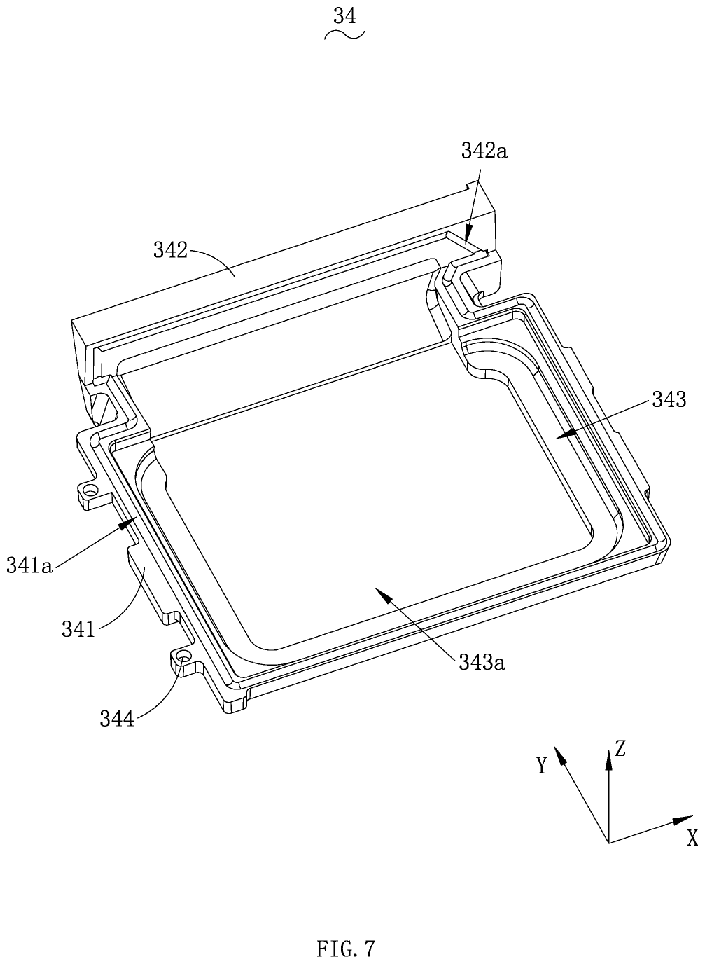

FIG. 7 is a top view of a lower bracket in FIG. 2.

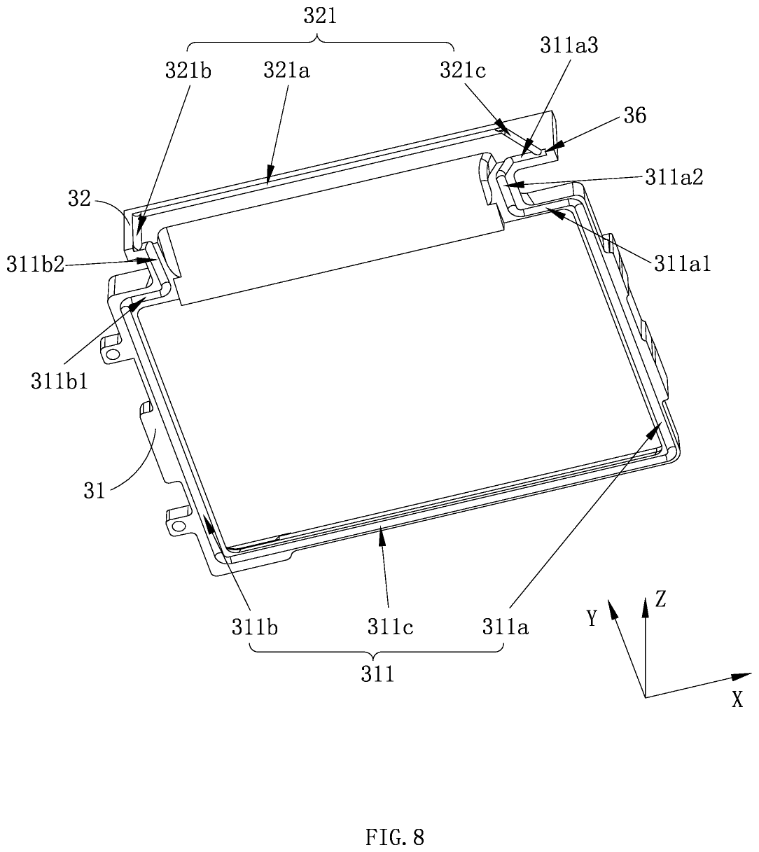

FIG. 8 is a schematic view of a first cooling channel and a second cooling channel in the speaker module according to an embodiment of present application.

### REFERENCE NUMBER

1—Casing;
11—Accommodating cavity;
12—Upper cover;
   121—Opening;
13—Base;
2—speaker driver;
3—Heat dissipation bracket;
   31—Body portion;
   311—First cooling channel;
   311a—First channel;
      311a1—First bent channel;
      311a2—Second bent channel;
      311a3—Fifth bent channel;
   311b—Second channel;
      311b1—Third bent channel;
      311b2—Fourth bent channel;
   311c—Third channel;
32—Extension portion;
   321—Second cooling channel;
      321a—Fourth channel;
      321b—Fifth channel;
      321c—Sixth channel;
33—Upper bracket;
   331—First body;
      331a—First groove channel;
      332—First extension portion;
      332a—Second groove channel;
   333—Mounting hole;
   334—Mounting portion;
34—Lower bracket;
   341—Second body;
      341a—Third groove channel;
   342—Second extension portion;
      342a—Fourth groove channel;
   343—Mounting groove;
      343a—Second through hole;
   344—Mounting matching portion;
35—First through hole;
36—Liquid injection port;
4—Connecting member.

The accompanying drawings are incorporated into and form a part of the specification, illustrate embodiments consistent with the present application and are used in conjunction with the specification to explain the principles of the present application.

### BEST EMBODIMENTS FOR PRACTICING THE INVENTION

### Best Embodiments for the Invention

The present application will be further described below with reference to the accompanying drawings and embodiments.

It should be clear that the described embodiments are only some of the embodiments of the present application. Based on the embodiments in the application, all other embodiments obtained by a person of ordinary skill in the art without creative labor are within the scope of protection of this application.

The present application provides a speaker module arranged in terminal devices (including but not limited to mobile phones and computers). A specific structure of the speaker module is shown in FIGS. 1 and 2. The speaker module includes a casing 1, a speaker driver 2 arranged inside an accommodating cavity 11 of the casing 1, and a heat dissipation bracket 3 arranged around the speaker unit 2. A material of the heat dissipation bracket 3 is a metal with good thermal conductivity, including but not limited to copper and copper alloy. For ease of understanding, as shown in FIG. 1, the speaker module provided by the present application has a first direction X, a second direction Y and a third direction Z. The first direction X is perpendicular to the second direction Y, and the first direction X is perpendicular to the third direction Z. The second direction Y is perpendicular to the third direction Z.

As shown in FIG. 1 and FIG. 2, the casing 1 includes an upper cover 12 and a base 13 that are arranged opposite to each other along the second direction Y and are configured to enclose the accommodating cavity 11. The upper cover 12 is provided with an opening 121. When the upper cover 12 is connected to the base 13, a part of the heat dissipation bracket 3 can extend out of the casing 1 through the opening 121. The upper cover 12 and the base 13 are integrally formed or detachably connected. When the upper cover 12 and the base 13 are integrally formed, the structural stability of the casing 1 can be increased. When the upper cover 12 and the base 13 are detachably connected, the mounting, maintenance and replacement of internal parts of the accommodating cavity 11 can be facilitated. In the present application, the connection method between the upper cover 12 and the base 13 are not specifically limited.

As shown in FIG. 1 and FIG. 2, the heat dissipation bracket 3 includes a body portion 31. A part of the body portion 31 is arranged in the accommodating cavity 11, and the other part of the body portion 31 is extended to the outside of the casing 1, and the body portion 31 is located in the casing 11. One end of the body portion 31 on an outside of the casing 1 is provided with an extension portion 32 that is bent and extended upward along a thickness direction of the speaker module (i.e., along the third direction Z), and the extension portion 32 is in abutted against heat dissipation members (not shown in the accompanying drawings) outside the speaker module. The heat dissipation members include but are not limited to a middle frame and a casing of the terminal device, and a material of the heat dissipation members is metal or other materials with good thermal conductivity. In addition, the body portion 31 is provided with a first cooling channel 311, and the first cooling channel 311 is arranged around the speaker driver 2. The extension portion 32 is provided with a second cooling channel 321 communicating with the first cooling channel 311, and the second cooling channel 321 is extended away from the speaker driver 2 along the third direction Z.

In this embodiment, the interior of the heat dissipation bracket 3 is provided with a first cooling channel 311 surrounding the speaker driver 2 and configured to accommodate the cooling liquid, and a second cooling channel 321 abutted against the heat dissipation members outside the speaker module and configured to accommodate the cooling liquid. Therefore, the heat generated by the vibration of the speaker driver 2 can be transferred to the heat dissipation bracket 3, and then transferred to the outside air and heat dissipation members through the cooling liquid in the first cooling channel 311 and the second cooling channel 321, so as to reduce a temperature of the speaker driver 2. Besides, since the extension portion 32 is located outside the accommodating cavity 11 and is abutted against the heat dissipation members, so that the temperature of the cooling liquid in the second cooling channel 321 is lower than the temperature of the cooling liquid in the first cooling channel 311, and the pressure in the second cooling channel 321 is lower than the pressure in the first cooling channel 311. Therefore, the high-temperature cooling liquid in the first cooling channel 311 flows to the second cooling channel 321 under the action of the pressure difference, thereby realizing the circulating flow of the cooling liquid, and further improving the heat dissipation efficiency of the heat dissipation bracket 3.

Specifically, as shown in FIG. 2 and FIG. 3, the heat dissipation bracket 3 includes an upper bracket 33 and a lower bracket 34 that are detachably connected or fixedly connected. In the present application, as shown in FIG. 3 and FIG. 4, the upper bracket 33 is provided with a mounting portion 334, and the lower bracket 34 is provided with an mounting matching portion 344. The mounting portion 334 is connected to the mounting matching portion 344 by a connecting member 4, so as to realize a detachable connection between the upper bracket 33 and the lower bracket 34, and facilitate the mounting and dismantling of the mounting bracket. The types of the connecting member 4 include, but are not limited to bolts, screws and positioning posts.

More specifically, as shown in FIG. 4, the upper bracket 33 includes a first body 331 and a first extension portion 332. The lower bracket 34 includes a second body 341 and a second extension portion 342. The first body 331 and the second body 341 are stacked along the third direction Z, and the first extension portion 332 and the second extension portion 342 are stacked along the second direction Y. After the upper bracket 33 and the lower bracket 34 are connected, the first extension portion 332 and the second extension portion 342 are jointed together to form the extension portion 32 of the heat dissipation bracket 3. The first body 331 and the second body 341 are jointed to form the body portion 31 of the heat dissipation bracket 3, and the extension portion 32 is extended upward in the third direction Z relative to the body portion 31. Therefore, there is a preset angle (the angle includes but not limited to 90°, 60°,) 45° between a plane where an axis of the first cooling channel 311 is located and a plane of an axis where the second cooling channel 321 is located, so that the second cooling channel 321 is abutted against the heat dissipation members for conducting heat, thereby simplifying a structure of the heat dissipation bracket 3.

As shown in FIG. 5, the heat dissipation bracket 3 is provided with a first through hole 35, and at least part of the first through hole 35 is located in a space enclosed by the second cooling channel 321, so as to increase a contact area between the second cooling channel 321 and the air, thereby improving the heat dissipation efficiency of the heat dissipation bracket 3. Besides, it can ensure a structural strength of the heat dissipation bracket 3 while reducing the materials required for processing the heat dissipation bracket 3, so as to reduce the processing cost of the heat dissipation bracket 3, and reduce a weight of the heat dissipation bracket 3.

As shown in FIG. 6 and FIG. 7, the upper bracket 33 is provided with a mounting hole 333 arranged through the first body 331 along the third direction Z, and the lower bracket 34 is provided with a mounting groove 343. The mounting hole 333 is arranged opposite to the mounting groove 343, and a part of the speaker driver 2 is extended into the mounting hole 333 and abutted against a bottom wall of the mounting groove 343, so as to simplify the connection between the speaker driver 2 and the heat dissipation bracket 3, thereby simplifying the structure of the speaker driver 2 and the heat dissipation bracket 3. A connection method of the speaker driver 2 and the bottom wall of the mounting groove 343 includes but is not limited to bonding and welding. In addition, as shown in FIG. 7, the bottom wall of the mounting groove 343 is provided with a second through hole 343a, and a part of the speaker driver 2 is exposed in the accommodating cavity 11 through the second through hole 343a, thereby increasing the contact area between the speaker driver 2 and the air. If the heat dissipation bracket 3 fails to work normally, the speaker driver 2 can also dissipate heat through the air in the accommodating cavity 11, which increases the heat dissipation path of the speaker driver 2, and further increases the heat dissipation efficiency and heat dissipation stability of the speaker module.

In addition, as shown in FIG. 6 and FIG. 7, the first body 331 of the upper bracket 33 is provided with a first groove channel 331a. The first extension portion 332 is provided with a second groove channel 332a. The second body 341 of the lower bracket 34 is provided with a third groove channel 341a. The second extension portion 342 is provided with a fourth groove channel 342a. After the upper bracket 33 and the lower bracket 34 are connected, the first groove channel 331a and the third groove channel 341a enclose the first cooling channel 311, and the second groove channel 332a and the fourth groove channel 342a enclose the second cooling channel 321, so as to facilitate the processing of the first cooling channel 311 and the second cooling channel 321, thereby reducing the number of processes required for processing the heat dissipation bracket 3, and further reducing the processing cost of the heat dissipation bracket 3.

Specific structures of the first cooling channel 311 and the second cooling channel 321 are shown in FIG. 8 (a bottom view of the above bracket 33 is taken as an example). The first cooling channel 311 includes: the first channel 311a and the second channel 311b oppositely arranged along the first direction X, the third channel 311c extended along the first direction X and capable of connecting the first channel 311a and the second channel 311b, the first channel 311a, the second channel 311b and the third channel 311c for surrounding the speaker unit 2. The second cooling channel 321 includes: the fourth channel 321a extended along the first direction X, the fifth channel 321b extended along the third direction Z and capable of communicating with the fourth channel 321a and the second channel 311b, and the sixth channel 321c capable of connecting the first channel 311a and the four channels 321a. An inner diameter of the sixth channel 321c is smaller than an inner diameter of the fifth channel 321b, so that the pressure in the sixth channel 321c is higher than the pressure in the fifth channel 321b, resulting in a preset flow trajectory of the cooling liquid, that is, the first channel 311a—the sixth channel 321c—the fourth channel 321a—the fifth channel 321b—the second channel 311b—the third channel 311c—the first channel 311a. The cooling liquid has a stable flow trajectory in the heat dissipation bracket 3, which reduces the risk of blocking the first cooling channel 311 or the second cooling channel 321 due to a opposite direction of the cooling liquid flow, thereby improving the stability of the cooling liquid flow, and further improving the working stability of the heat dissipation bracket 3.

More specifically, as shown in FIG. 8, one end of the first channel 311a is provided with a first bent channel 311a1 toward the second channel 311b extended along the first direction X, and one end of the second channel 311b is provided with a first bent channel 311a1 toward the first channel 311a along the first direction X, so as to increase the contact area between the first cooling channel 311 and the speaker driver 2, and further improve the heat dissipation efficiency of the heat dissipation bracket 3. The first channel 311a is further provided with a second bent channel 311a2 bent and extended along the second direction Y, and a fifth bent channel 311a3 bent and extended away from the second channel 311b along the first direction X. The first bent channel 311a1 and the sixth channel 321c are communicated through the second bent channel 311a2 and the fifth bent channel 311a3. The second channel 311b is further provided with a fourth bent channel 311b2 bent and extended along the second direction Y and capable of communicating with the third bent channel 311b1 and the fifth channel 321b, so as to facilitate the communication between the second cooling channel 321 and the first cooling channel 311, thereby simplifying the structures of the second cooling channel 321 and the first cooling channel 311, and further reducing the processing cost of the second cooling channel 321 and the first cooling channel 311.

In addition, the heat dissipation bracket 3 is provided with a liquid injection port 36, and the first cooling channel 311 and the second cooling channel 321 may be communicated with the outside through the liquid injection port 36, so as to inject the cooling liquid into the first cooling channel 311 and the second cooling channel 321. In the present application, the specific position, shape and size of the liquid injection port 36 are not particularly limited. In the present application, as shown in FIG. 8, the liquid injection port 36 is communicated with the fifth bent channel 311a3 and is located on one end of the fifth bent channel 311a3 away from the second bent channel 311a2.

Described above are only embodiments of the present application. It should be pointed out that for those of ordinary skill in the art, improvements may be made without departing from the inventive concept of the present application, but these improvements belong to protection scope of the present application.

1. A speaker module, comprising:
a casing provided with an accommodating cavity;
a speaker driver arranged in the accommodating cavity;
a heat dissipation bracket, comprising a body portion, wherein a part of the body portion is arranged in the accommodation cavity, and the other part of the body portion is arranged on an outer side of the casing; one end of the body portion located on the outer side of the casing is provided with an extension portion that is bent and extended upward along a thickness direction of the speaker module, and the extension portion is abutted against heat dissipation members outside the speaker module;
the body portion is provided with a first cooling channel, wherein the first cooling channel is arranged around the speaker driver; the extension portion is provided with a second cooling channel communicated with the first cooling channel; the second cooling channel is extended away from the speaker driver along the thickness direction of the speaker module, and the first cooling channel and the second cooling channel are filled with cooling liquid.

2. The speaker module of claim 1, wherein a plane where an axis of the first cooling channel is located is a first plane, a plane where an axis of the second cooling channel is located is a second plane, and there is a preset angle between the first plane and the second plane.

3. The speaker module of claim 2, wherein the first cooling channel comprises a first channel and a second channel that are oppositely arranged along a first direction, and a third channel extended along the first direction and capable of communicating with the first channel and the second channel;
the second cooling channel comprises a fourth channel extended along the first direction, a fifth channel extended along a third direction and capable of communicating with the fourth channel and the second channel, and a sixth channel capable of communicating with the first channel and the fourth channel;
the first direction is perpendicular to the third direction.

4. The speaker module of claim 3, wherein an inner diameter of the sixth channel is smaller than an inner diameter of the fifth channel.

5. The speaker module of claim 3, wherein one end of the first channel is provided with a first bent channel extended toward the second channel along the first direction, and a second bent channel extended along a second direction and capable of communicating with the first bent channel and the sixth channel;
one end of the second channel is provided with a third bent channel extended toward the first channel along the first direction, and a fourth bent channel extended along the second direction and capable of communicating with the third bent channel and the fifth channel;
the second direction is perpendicular to both the first direction and the third direction.

6. The speaker module of claim 1, wherein the heat dissipation bracket is provided with a first through hole arranged through a side wall of the heat dissipation bracket along the second direction, and at least part of the first through hole is located in a space enclosed by the second cooling channel.

7. The speaker module of claim 1, wherein the heat dissipation bracket comprises an upper bracket and a lower bracket, wherein the upper bracket comprises a first body and a first extension portion, and the lower bracket comprises a second body and a second extension portion;
the first body and the second body are stacked along the third direction, and the first extension portion and the second extension portion are stacked along the second direction.

8. The speaker module of claim 7, wherein the first body is provided with a first groove channel; the first extension portion is provided with a second groove channel; the second body is provided with a third groove channel, and the second extension portion is provided with a fourth groove channel;
after the upper bracket and the lower bracket are connected, the first groove channel and the third groove channel enclose the first cooling channel, and the second groove channel and the fourth groove channel enclose the second cooling channel.

9. The speaker module of claim 7, wherein the upper bracket is provided with a mounting hole; the lower bracket is provided with a mounting groove; the mounting hole is arranged opposite to the mounting groove, and a part of the speaker driver is extended into the mounting hole and is abutted against a bottom wall of the mounting groove;
the bottom wall of the mounting groove is provided with a second through hole, and a part of the speaker driver is exposed in the accommodating cavity through the second through hole.

10. (canceled)
